(19) United States
(12) Patent Application Publication
(10) Pub. No.: US 2026/0123432 A1
(43) Pub. Date: Apr. 30, 2026

(54) CHIP PACKAGE WITH FLANGED STIFFENER

(71) Applicant: Advanced Micro Devices, Inc., Santa Clara, CA (US)

(72) Inventors: Priyal SHAH, Bangalore (IN); Kaushik MYSORE, Austin, TX (US); Deepak Vasant KULKARNI, Austin, TX (US)

(21) Appl. No.: 18/927,531

(22) Filed: Oct. 25, 2024

(51) Int. Cl. H01L 23/00; H01L 21/48; H01L 23/10; H01L 23/29; H01L 23/31; H01L 23/367; H01L 25/16

(52) U.S. Cl. CPC H10W 42/121; H10W 40/22; H10W 74/141; H10W 76/60; H10W 90/00; H10W 99/00; H10D 1/68; H10W 72/07354; H10W 72/347; H10W 74/47; H10W 90/734

(57) ABSTRACT

Disclosed herein are chip packages having stiffeners and methods for making the same. In one example, a chip package includes a substrate, an integrated circuit (IC) die complex, a spacer, and a stiffener. The IC die complex is mechanically connected to the substrate. The spacer is formed on a top surface of the substrate outward of the IC die complex. The stiffener includes a ring base and a flange that extends inward from the ring base. The ring base has a bottom surface that is attached to the top surface of the substrate. The flange has a bottom surface attached to the top surface of the spacer. The attachment to the stiffener at inner and outer locations provides enhanced resistance to warpage.

### TECHNICAL FIELD

Embodiments of the present disclosure generally relate to chip packages and techniques for manufacturing the same. In particular, to a chip package having a flanged stiffener that promotes warpage resistance.

### BACKGROUND

Electronic devices, such as tablets, computers, server, in-door telecom, out-door telecom, industrial computers, high performance computing data centers, copiers, digital cameras, smart phones, control systems and automated teller machines, among others, often employ electronic components which leverage chip package assemblies for increased functionality and higher component density. Conventional chip package assemblies include one or more stacked components such as integrated circuit (IC) dies, through-silicon-via (TSV) interposer, and a package substrate, with the chip package itself stacked on a printed circuit board (PCB). The IC dies may include memory, logic, MEMS, RF or other IC device.

With progressive increase in package body size for high-performance compute and machine learning packages, the amount of package warpage has undesirably also increase. The amount of heat produced by these high-performance packages is also increasing, which requires efficient thermal solutions in order to effectively dissipate the generated heat. At the same time, there is a need to shrink ball grid array (BGA) pitches to further enable high speed signaling. However, larger packages with high warpages and tighter BGA pitches present significant challenges as such packages impose a very high risk of yield loss during surface mounting to PCBs.

Moreover, effectively testing test packages having large body sizes when excessive warpage also presents significant challenges.

Therefore, a need exists for an improved chip package.

### SUMMARY

Disclosed herein are chip packages having stiffeners and methods for making the same. In one example, a chip package includes a substrate, an integrated circuit (IC) die complex, a spacer, and a stiffener. The IC die complex is mechanically connected to the substrate. The spacer is formed on a top surface of the substrate outward of the IC die complex. The stiffener includes a ring base and a flange that extends inward from the ring base. The ring base has a bottom surface that is attached to the top surface of the substrate. The flange has a bottom surface attached to the top surface of the spacer. The attachment to the stiffener at inner and outer locations provides enhanced resistance to warpage.

In another example, a chip package includes a substrate, an integrated circuit (IC) die complex, a spacer, and a stiffener. The IC die complex is mechanically connected to the substrate. The IC die complex includes at least one compute die having central processing unit (CPU) cores and/or accelerated compute cores. The spacer is formed on a top surface of the substrate and surrounds the IC die complex. The spacer is fabricated from a polymeric material. The stiffener includes a base ring and a flange. The ring base has a bottom surface attached to the top surface of the substrate. The flange extends inward from the ring base and has a bottom surface attached by an adhesive to the top surface of the spacer. An inner wall of the flange defines an opening through which a top surface of the IC die complex is exposed.

In yet another example, a method for fabricating a chip package is provided that includes attaching an integrated circuit (IC) die complex to a substrate; disposing a spacer on a top surface of the substrate, the spacer at least partially surrounding the IC die complex; and attaching a stiffener to the top surface of the substrate and to a top surface of the spacer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional schematic view of one example of an integrated chip package having a flanged stiffener.

FIGS. 2A-2C are cross sectional schematic views of other examples of an integrated chip package having a flanged stiffener.

FIG. 3 is a cross sectional schematic view of an integrated chip package mounted on a printed circuit board to form an electronic device.

FIG. 4 is a flow diagram of a method for forming a chip package.

FIGS. 5A-5F are sectional schematic views of a chip package in different stages of assembly.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Embodiments of the disclosure generally provide chip packages and methods for fabricating the same that leverage a flanged stiffener to mitigate warpage. The novel chip package includes a spacer, disposed on a substrate, outward of a chip complex. The stiffener includes integrating a ring base and a flange that extends inwardly from the ring base. The stiffener is attached to a periphery of the substrate as well as to the spacer using adhesive materials. The attachment of the stiffener at inner and outer locations provides enhanced resistance to warpage, thus making the chip package much more robust and reliable compared to conventional designs. Moreover, surface mounted components, such as capacitors and the like, can be protectively encapsulated by the spacer. In other examples, the ring-shaped stiffener includes a central opening through which the top surface of the chip complex is exposed, thus allowing thermal solutions to be directly interfaced with the chip complex (i.e., without an intervening lid or cover) resulting in enhanced heat transfer and computing performance.

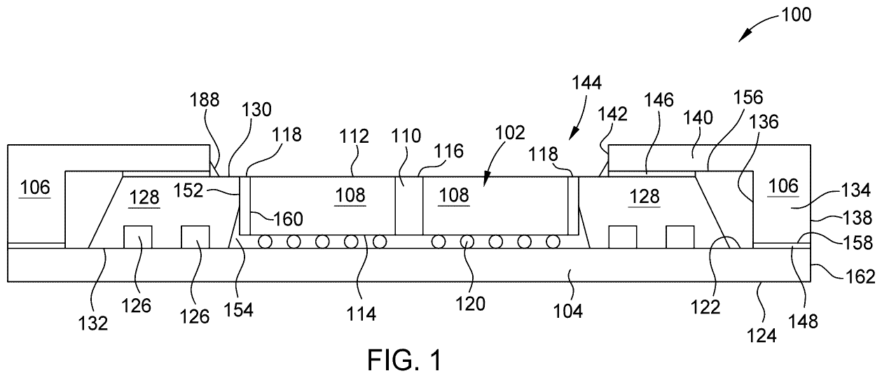

Turning now to FIG. 1, an integrated circuit (IC) chip package 100 is illustrated having a flanged stiffener 106. The IC package 100 also includes a substrate 104, an integrated circuit (IC) die complex 102, and a spacer 128. The IC die complex 102 is mechanically connected to the substrate 104. The substrate 104 may be a package substrate as shown in FIG. 1, or be a combination of an interposer mounted on a package substrate. A bottom surface 124 of the substrate 104 generally includes a plurality of contact pads that facilitate communicatively connecting of the substrate 104 to a printed circuitry board (PCB), not shown. The substrate 104 may be connect to PCB through solder balls, through use of a socket, wire bonding, or other suitable technique. The spacer 128 is formed or otherwise disposed on substrate 104 outward of the IC die complex 102. The stiffener 106 is attached to the components of the chip package 100 at inner and outer locations, which enhances the resistance of the substrate 104 to warpage, resulting in more reliable connections between the components of the chip package 100 and more robust and reliable performance.

The IC die complex 102 generally includes at least one or more integrated circuit (IC) dies 108. Although two IC dies 108 are illustrated in FIG. 1, one to as many IC dies 108 that can fit on the substrate 104 may be utilized. The IC dies 108 of the IC die complex 102 may be surrounded by a mold compound 110. The mold compound 110 generally provides structural rigidity to the assembly of memory dies 108 comprising the IC die complex 102. The mold compound 110 is generally a polymer, such as epoxy.

As discuss above, the compute die complex 102 generally includes at least one IC die 108. The compute die complex 102 may also include an optional active interposer on which the one or more IC dies 108 are mounted. In the example depicted in FIG. 1, two IC dies 108 are shown mounted side by side on the substrate 104. Alternatively or in addition to what is shown in FIG. 1, one or more other IC dies 108 may be stacked on one or more of IC dies 108 illustrated in FIG. 1.

Each IC die 108 includes functional circuitry. The functional circuitry of each IC die 108 in a common compute die complex 102 may be the same or different. In one example, at least one or both of the first IC die 108 and the second IC die 108 include central processing unit (CPU) cores. As such, the first and second IC dies 108 containing CPU cores may be referred to as a CPU die or CPU chiplet. The functional circuitry of the first and second IC dies 108 may also include System Management Unit (SMU). The SMU is circuitry configured to monitor thermal and power conditions and adjust power and cooling to keep the dies 108 functioning as within specifications. The functional circuitry of the first and second IC dies 108 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry of at least one or both of the first IC die 108 and the second IC die 108 include accelerated compute cores. As such, each of the first and second IC dies 108 containing accelerated compute cores may be referred to as an accelerator die or accelerator chiplet. The first and second IC dies 108 containing accelerated compute cores may also be referred to as a graphic processing unit (GPU) die or GPU chiplet. The accelerated compute cores contained in the functional circuitry of the first and second IC dies 108 generally includes math engine circuitry. The math engine circuitry is generally designed for task specific computing, such as used data center computing, high performance computing and AI/ML computing. Along with the accelerated compute cores, functional circuitry of the first IC die 108 and the second IC die 108 may also include SMU circuitry and DFX circuitry.

In other examples, the functional circuitry the first IC die 108 and the second IC die 108 are different. For example, the first IC die 108 may include accelerated compute cores, while the second IC die 108 includes CPU cores. One or more compute dies, when present in the compute stack 102, may include CPU cores and/or an accelerated compute cores. In other examples, the first IC die 108 may include CPU and/or accelerated compute cores, while the second IC die 108 may be one of a stack of memory dies containing memory circuitry, such as to form a high bandwidth memory (HBM) device.

The functional circuitries the first IC die 108 and the second IC die 108 terminate at contact pads (not shown) exposed on a bottom surface 114 of each IC die 108. The contact pads are electrically and mechanically coupled contact pads exposed on a top surface 122 of the substrate 104. The solder interconnects 120 may be microbumps or other suitable connection that mechanically and electrically connects the routing of the substrate 104 to the functional circuitries of the IC dies 108 of the IC die complex 102.

Each IC die 108 of the IC die complex 102 also includes a top surface 112. The mold compound 110 encapsulating the IC dies 108 also includes a top surface 116. The top surfaces 112, 116 may be made substantially coplanar, for example, by grinding, milling, etching or other suitable technique. A portion of the mold compound 110 disposed outward of the sidewalls 160 of the IC dies 108 is referred to as a margin 118 of the mold compound 110. The laterally outer surface of the margin 118 defines an outer sidewall 152 of the IC die complex 102.

A bottom surface 114 of the IC dies 108 are connected to a top surface 122 of the substrate 104 by solder interconnects 120. The solder interconnects 120, such as micro-bumps, mechanically and electrically connect the functional circuitry of the IC dies 108 to the routing circuitry of the substrate 104. Stated differently, the solder interconnects 120 coupled the IC die complex 102 to the top surface 122 of the substrate 104.

Underfill 154 is disposed in the interstitial spaces between the bottom surface 114 of the IC dies 108 and the top surface 122 of the substrate 104, thereby providing structural rigidity to the chip package 100. The underfill 154 also surrounds and protects the solder interconnects 120. The underfill 154 may be an epoxy or other suitable material. The underfill 154 generally contacts the top surface 122 of the substrate 104 and also the outer sidewall 152 of the IC die complex 102. In the example depicted in FIG. 1, the underfill 154 extends about half way up the outer sidewall 152 of the IC die complex 102, leaving an upper portion of the outer sidewall 152 exposed (i.e., free from underfill 154).

The substrate 104 may also include a plurality of surface mounted components 126. The surface mounted components 126 are coupled to functional circuitry of the IC dies 108 through the routing formed in the substrate 104. The surface mounted components may be integrated passive devices (IPDs), such as capacitors, inductors, and resistors, among others. In one example, the surface mounted components are capacitors. In addition or alternatively, some or all of the surface mounted components may be located as IPDs in other locations of the chip package 100. In the example depicted in FIG. 1, the surface mounted components 126 are in the form of capacitors mounted to the substrate 104 outward of the outer sidewall 152 of the IC die complex 102 and inward of the stiffener 106. The surface mounted components 126 may also be mounted to the substrate 104 outward of the underfill 154.

The spacer 128 is also mounted on the substrate 104. The spacer 128 is comprised of a polymeric material, such as a mold compound, for example an epoxy.

The spacer 128 generally is disposed outward of, and surrounds the IC die complex 102.

The spacer 128 has a top surface 130 and a bottom surface 132. The bottom surface 132 of the spacer 128 is disposed on the top surface 122 of the substrate 104. In one example, the spacer 128 encapsulates some or all of the surface mounted components 126 disposed on the top surface 122 of the substrate 104. The spacer 128 may touch or alternatively be spaced from the outer sidewall 152 of the IC die complex 102. In the example depicted in FIG. 1, the spacer 128 is in contact with at least the upper portion of the outer sidewall 152 of the IC die complex 102. The spacer 128 may also be in contact with the underfill 154.

The top surface 130 of the spacer 128 may be parallel or disposed at an acute angle with the top surface 122 of the substrate 104. The top surface 130 of the spacer 128 may be disposed at the same or different elevation as the top surface 112 of the IC die 108/IC die complex 102. In the example depicted in FIG. 1, the top surface 130 of the spacer 128 is substantially coplanar with the top surface 112 of the IC die 108/IC die complex 102.

The stiffener 106 is generally coupled to the chip package 100 outward of the IC die complex 102. The stiffener 106 includes a ring base 134 and a flange 140. The ring base 134 has a bottom surface 158, an inner wall 136 and an outer wall 138. The bottom surface 158 of the ring base 134 is disposed on the top surface 122 of the substrate 104. The inner wall 136 of the ring base 134 faces the IC die complex 102 and spacer 128. In the example depicted in FIG. 1, the inner wall 136 of the ring base 134 is spaced from the outer edge of the spacer 128. The outer wall 138 of the ring base 134 is disposed at or near a peripheral edge 162 of the substrate 104.

The flange 140 extends from the inner wall 136 of the ring base 134 inward towards the IC die complex 102. The flange 140 is generally spaced above the bottom surface 158 of the ring base 134 and the top surface 122 of the substrate 104. The flange 140 includes an inner wall 142 that defines an opening 144 through the stiffener 106 through which the top surface 112 of the IC dies 108/IC die complex 102 is exposed.

The flange 140 includes a bottom surface 156 that extends over the top surface 130 of the spacer 128. The bottom surface 156 of the flange 140 is generally parallel with the top surface 130 of the spacer 128, and in one example, the bottom surface 156 of the flange 140 is also parallel with the top surface 122 of the substrate 104. The inner wall 142 of the flange 140 may also be disposed over the top surface 130 of the spacer 128, but may alternatively extend inward over the margin 118 or even over the IC die 108.

As stated above, the stiffener 106 is generally coupled to the chip package 100 outward of the IC die complex 102 in at least two places that are inward and outward of each other. The stiffener 106 is generally mounted at a peripheral edge 162 of the substrate 104 and circumscribes the IC die complex 102. The stiffener 106 provides mechanical support which helps prevent the substrate 104, and consequently the chip package 100, from bowing and warping. The stiffener 106 may be a single layer structure or a multi-layer structure. The stiffener 106 may be made of ceramic, metal or other various inorganic materials, such as aluminum oxide (Al₂O₃), aluminum nitride (AlN), silicon nitride (SiN), silicon (Si), copper (Cu), aluminum (Al), and stainless steel, among other materials. The stiffener 106 can also be made of organic materials such as copper-clad laminate.

In one example, stiffener 106 is coupled to the top surface 122 of the substrate 104 and the top surface 130 of the spacer 128. The stiffener 106 is coupled to the top surface 122 of the substrate 104 at or near the peripheral edge 162 of the substrate 104. The stiffener 106 may be coupled to the top surface 122 of the substrate 104 by any suitable technique, such as bonding, screwing, and clamping. The stiffener 106 is coupled to the top surface 130 of the spacer 128 at a location inward of the location at which the stiffener 106 is coupled to the top surface 122 of the substrate 104. The stiffener 106 may be coupled to the top surface 130 of the spacer 128 by any suitable technique, such as bonding, screwing, and clamping. The location at which the stiffener 106 is coupled to the top surface 130 of the spacer 128 is at a different elevation relative to the substrate 104 than the location at which the stiffener 106 is coupled to the top surface 122 of the substrate 104.

In the example depicted in FIG. 1, the bottom surface 156 of the flange 140 is secured to the top surface 130 of the spacer 128 by a first adhesive 146, while the bottom surface 158 of the ring base 134 is secured to the top surface 122 of the substrate 104 by a second adhesive 148. Without limitation, the first and second adhesives 146, 148 may be dispensed-in-place, configured in strips, or be die cut. The first and second adhesives 146, 148 generally have an operational temperature greater than a BGA reflow temperature, such above 145 degrees Celsius. The adhesive 146, 148 may be an epoxy or other suitable bonding material. In one example, the adhesive 146, 148 is polymer based or silica based. The attachment of the stiffener 106 at both inner location (i.e., at the flange 140 and spacer 128) and an outer location (i.e., at the ring base 134 and peripheral edge 162 of the substrate 104) significantly enhances the resistance to warpage, thus making the substrate 104 and chip package 100 much more robust and reliable compared to conventional designs.

Optionally, a fillet 188 may be disposed between the inner wall 142 of the flange 140 and the top surface 130 of the spacer 128. The fillet 188 may be made from a polymer, such as epoxy, or other suitable material. The fillet 188 desirably reduces the stress within the first adhesive layer 146, making the retention of the flange 140 of the spacer 106 to the top surface 130 of the spacer 128 much more robust and reliable.

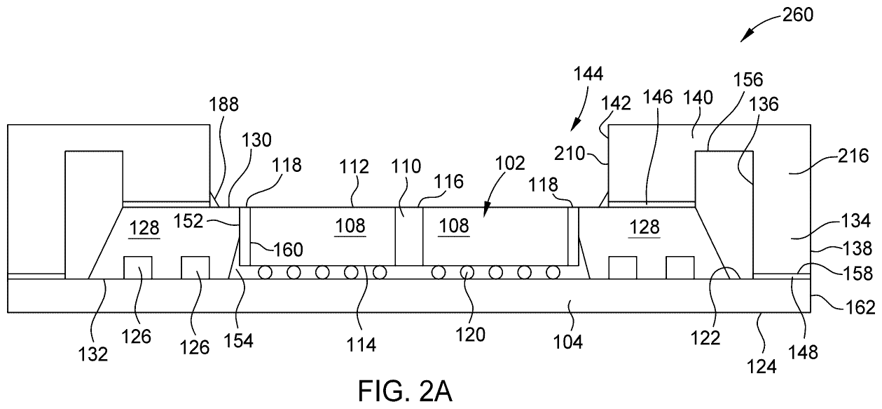

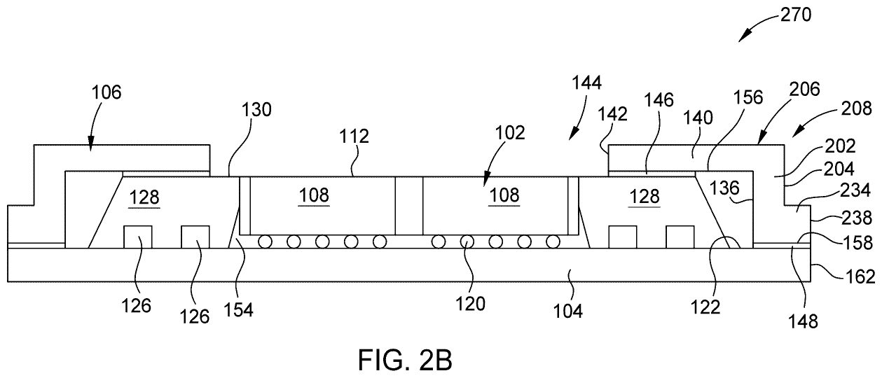

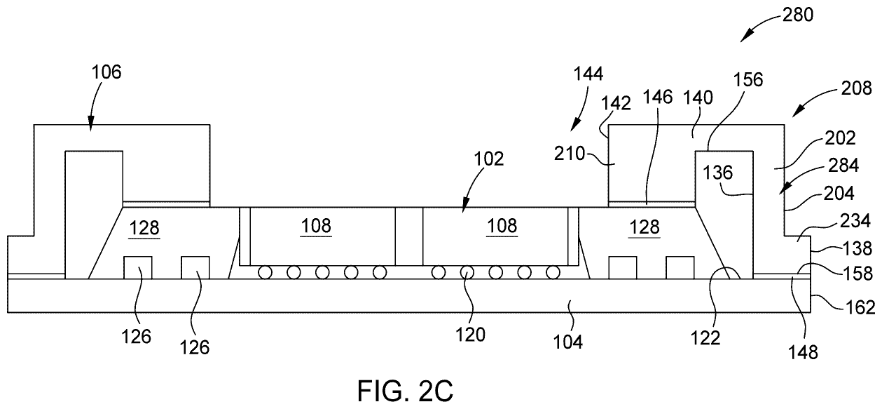

FIG. 2A is a cross sectional schematic view of another example of an integrated chip package 260 having a flanged stiffener 216. The integrated chip package 260 is essentially the same as the integrated chip package 100 described above with reference to FIG. 1, except that the bottom surface 156 the flange 140 of the stiffener 216 includes a downwardly projecting contact ring 210 as compared to the flat bottom flange 156 of the stiffener 106. The contact ring 210 includes additional corner geometries as compared to the stiffener 106, thus making the stiffener 216 more rigid. The contact ring 210 is generally disposed at or near the inner sidewall 142 of the stiffener 216. The first adhesive 146 secures the bottom surface of the contact ring 210 against the top surface 130 of the spacer 128.

FIG. 2B is a cross sectional schematic view of another example of an integrated chip package 270 having a flanged stiffener 206. The integrated chip package 270 is essentially the same as the integrated chip package 100 described above with reference to FIG. 1, except that the flanged stiffener 206 has a notch 208 formed at the top outer corner of the stiffener 206 as compared to the stiffener 106.

The flanged stiffener 206 includes a flange 140, a connector ring 202, and a ring base 234. The ring base 234 has an outer wall 238 that is deposed at the peripheral edge 162 of the substrate 104. The connector ring 202 couples the ring base 234 to the flange 140. The connector ring 202 has an outer wall 204 that is inwardly offset relative to the outer wall 238 of the ring base 234, thus defining the notch 208 at the top outer corner of the stiffener 206. The flange 140 is coupled to the connector ring 202 and extends inward towards the IC die complex 102 to the inner wall 142 that defines the opening 144 through which the top surface of the IC die complex 102 is exposed.

Similar to the stiffener 106, a bottom surface 156 of the flange 140 of the stiffener 206 is secured to the top surface 130 of the spacer 128 by a first adhesive 146, while the bottom surface 158 of the ring base 234 of the stiffener 206 is secured to the top surface 122 of the substrate 104 by a second adhesive 148.

FIG. 2C is a cross sectional schematic view of another example of an integrated chip package 280 having a flanged stiffener 284. The integrated chip package 280 is essentially the same as the integrated chip package 270 described above with reference to FIG. 2B, except that the bottom surface 156 the flange 140 of the stiffener 284 includes a downwardly projecting contact ring 210 as compared to the flat bottom flange 156 of the stiffener 216. The contact ring 210 includes additional corner geometries as compared to the stiffener 216, thus making the stiffener 284 more rigid. The contact ring 210 is generally disposed at or near the inner sidewall 142 of the stiffener 284. The first adhesive 146 secures the bottom surface of the contact ring 210 against the top surface 130 of the spacer 128.

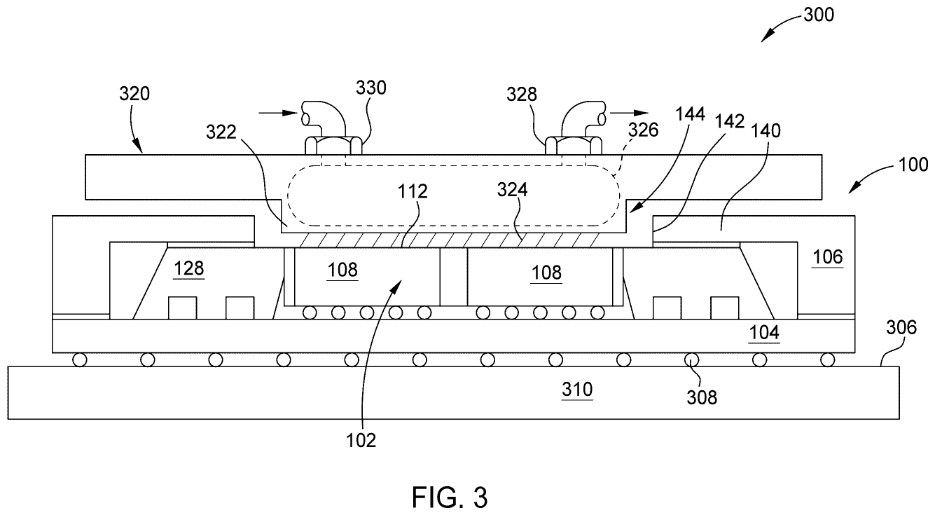

FIG. 3 is a cross sectional schematic view of an integrated chip package mounted on a printed circuit board (PCB) 310 to form an electronic device 300. The chip package illustrated in FIG. 3 may be the chip package 100 or 270 described above, or another chip package having a flanged stiffener. In the example depicted in FIG. 3, the chip package 100 is shown by way of example. The PCB 310 may be electrically and mechanically connected to the chip package 100 utilizing solder balls 308 or other suitable technique.

The chip package 100 may also be interfaced with a thermal regulating device 320. The thermal regulating device 320 includes an active and/or passive heat transfer elements, such as fins, forced liquid channels, forced gas channels, vapor cavities, phase change materials, and/or heat pipes, among other heat transfer enhancing elements. The thermal regulating device 320 is utilized to remove heat from the IC die complex 102, thus enhancing the reliability and performance of the IC dies 108, and consequently, improving the reliability and performance of the chip package 100 and electronic device 300. In the example depicted in FIG. 3, the thermal regulating device 320 includes one or more channels 226 coupled between an inlet port 330 and an outlet port 328 through which a vapor, gas and/or liquid may be passed to remove heat from the thermal regulating device 320.

The thermal regulating device 320 includes a pad 322 that extends through the opening 144 of the stiffener 106 into close proximity to the top of the IC die complex 102. A thermal interface material (TIM) 324 is disposed between the pad 322 and the top surfaces 112 of the IC dies 108 to improve the efficiency of heat transfer from the IC die complex 102 to the thermal regulating device 320.

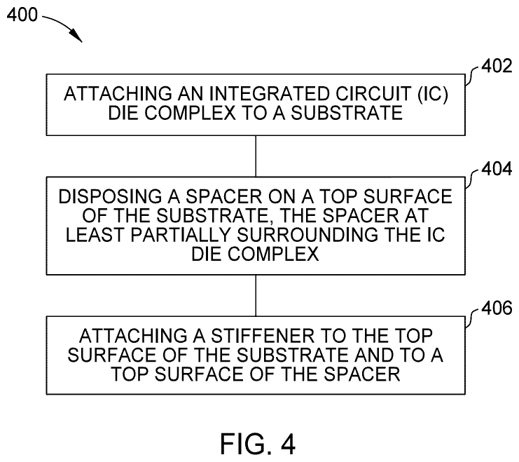

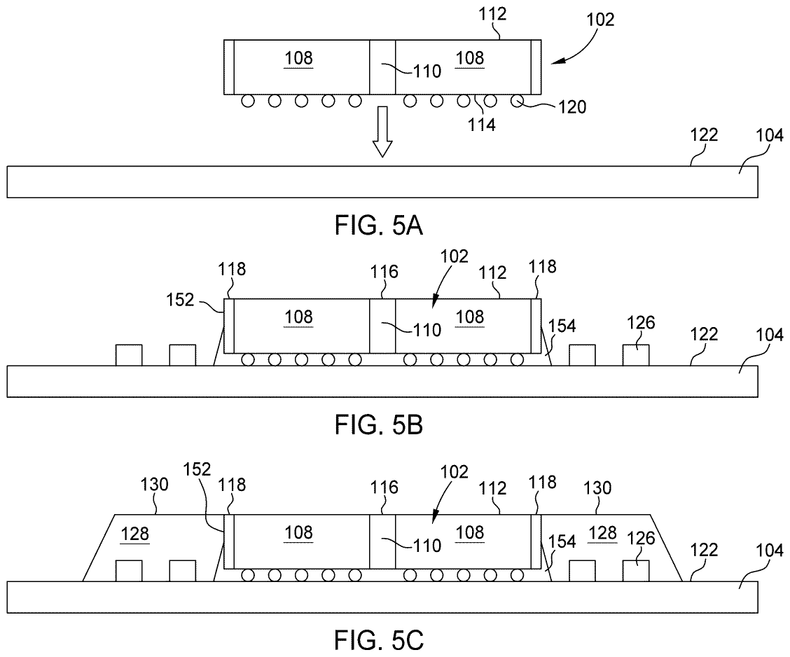

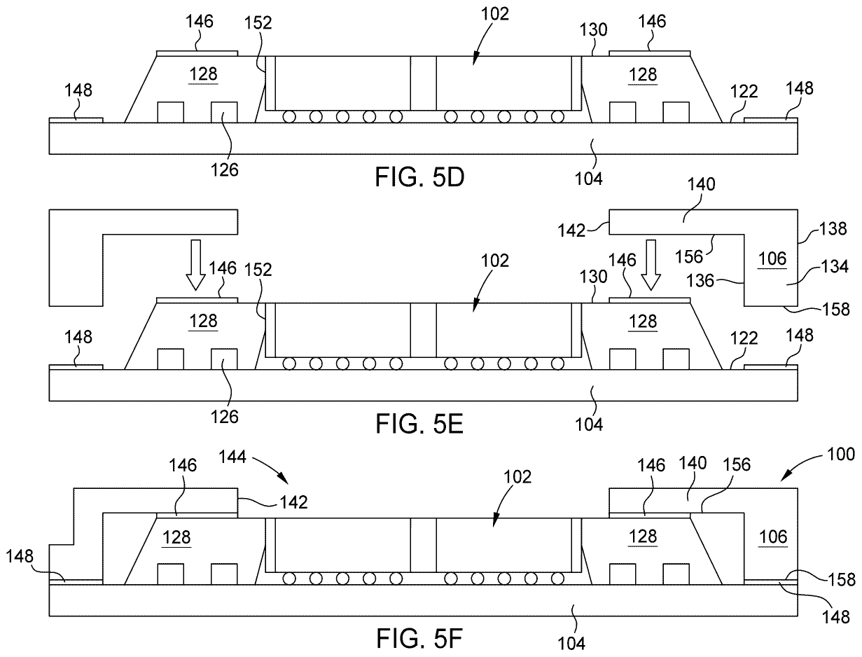

FIG. 4 is a flow diagram of a method 400 for forming a chip package, such as any of the chip packages described above, or other chip package that includes a flanged stiffener. FIGS. 5A-5F are sectional schematic views of one example of a chip package in different stages of assembly.

The method 400 for fabricating a chip package begins at operation 402 by attaching an integrated circuit (IC) die complex 102 to a substrate 104, as illustrated in FIG. 5A. The die complex 102 may be attached to the substrate 104 using solder interconnects 120 that mechanically and electrically couple the functional circuitry of the IC dies 108 of the routing circuitry of the substrate 104.

Operation 402 may also include depositing an underfill 154 between the die complex 102 and the substrate 104, as illustrated in FIG. 5B. Operation 402 may also include attaching surface mounted components 126 to the top surface 122 of the substrate 104, as also illustrated in FIG. 5B. The surface mounted components 126 are coupled to functional circuitry of the IC dies 108 through the routing formed in the substrate 104. The surface mounted components 126 may be integrated passive devices (IPDs), such as capacitors, inductors, and resistors, among others. In one example, the surface mounted components 126 are capacitors.

At operation 404, a spacer 128 is disposed on the top surface 122 of the substrate 104 outward of the IC die complex 102, as illustrated in FIG. 5C. The spacer 128 may comprise a polymeric material that is dispensed or otherwise disposed on the substrate 104. The spacer 128 may be spaced from, or disposed in contact with the outer sidewall 152 of the IC die complex 102 and/or the underfill 154. The spacer 128 may be disposed on the top surface 122 of the substrate 104 by molding, additive manufacturing, dispensing or other suitable technique.

At operation 404, the spacer 128 may be deposited on surface mounted components 126 disposed on the top surface 122 of the substrate 104. The spacer 128 generally encapsulates the surface mounted components 126.

Also at operation 404, the top surface 130 of the spacer 128 may be made parallel and optionally coplanar with the top surface 122 of the substrate 104. The geometry and location of top surface 130 of the spacer 128 may be configured through a molding process, or by mechanical removal through grinding, milling, etching or other technique.

At operation 406, a stiffener 106 is attached to the top surface 122 of the substrate 104 and to a top surface 130 of the spacer 128. The stiffener 106 is attached to the substrate 104 and the spacer 128 by deposing a first adhesive 146 on a top surface 130 of the spacer 128 and deposing a second adhesive 148 on a top surface 130 of the spacer 128 as illustrated in FIG. 5D, then pressing the stiffener 106 into contact with the adhesive 146, 148 disposed on the spacer 128 and substrate 104 as illustrated in FIG. 5D, to form the chip package 100 as illustrated in FIG. 5E. Alternative, operation 408 may be performed by first deposing the first adhesive 146 on the bottom surface 156 of the flange 140 of the stiffener 106 and deposing the second adhesive 148 on the bottom surface 158 of the stiffener 106, then pressing the adhesive 146, 148 secured to the stiffener 106 into contact with the spacer 128 and substrate 104 to form the chip package 100.

In addition to the examples described above, the disclosed technology may also be expressed in the following non-limiting examples.

Example 1. A chip package including: a substrate; an integrated circuit (IC) die complex mechanically connected to the substrate; a spacer formed on a top surface of the substrate outward of the IC die complex; and a stiffener. The stiffener including: a ring base having a bottom surface attached to the top surface of the substrate; and a flange extending inward from the ring base, the flange having a bottom surface attached to the top surface of the spacer.

Example 2. The chip package of Example 1, wherein an inner wall of the stiffener defines an opening through which a top surface of the IC die complex is exposed.

Example 3. The chip package of Example 1 further including: a first adhesive attaching the bottom surface of the flange to the top surface of the spacer.

Example 4. The chip package of Example 3 further including: a second adhesive attaching the bottom surface of the ring base to the top surface of the substrate.

Example 5. The chip package of Example 4, wherein at least one of the first and second adhesives have a service temperature of at least 240 degrees Celsius.

Example 6. The chip package of Example 4, wherein at least one of the first and second adhesives is polymer based or silica based.

Example 7. The chip package of Example 1 further including: underfill contacting one or more of an inner wall of the flange of the stiffener, the top surface of the spacer, and a top surface of the IC die complex is exposed.

Example 8. The chip package of Example 1, wherein the spacer is fabricated from a polymeric material.

Example 9. The chip package of Example 1, wherein the spacer encapsulates surface mounted components disposed on the substrate.

Example 10. The chip package of Example 9, wherein the surface mounted components are capacitors.

Example 11. A chip package including: a substrate; an integrated circuit (IC) die complex mechanically connected to the substrate, the IC die complex including at least one compute die having central processing unit (CPU) cores and/or accelerated compute cores; a spacer formed on a top surface of the substrate and surrounds the IC die complex, the spacer fabricated from a polymeric material; and a stiffener. The stiffener including: a ring base having a bottom surface attached to the top surface of the substrate; and a flange extending inward from the ring base, the flange having a bottom surface attached by an adhesive to the top surface of the spacer, an inner wall of the flange defining an opening through which a top surface of the IC die complex is exposed.

Example 12. The chip package of Example 11 further including: a thermal regulating device having a pad extending through the opening of the stiffener; and thermal interface material contacting the pad of the thermal regulating device and the top surface of the IC die complex.

Example 13. The chip package of Example 11, wherein the adhesive has a service temperature of at least 240 degrees Celsius.

Example 14. The chip package of Example 13, wherein the adhesive is polymer based or silica based.

Example 15. The chip package of Example 11 further including underfill contacting one or more of an inner wall of the flange of the stiffener, the top surface of the spacer, and a top surface of the IC die complex is exposed.

Example 16. The chip package of Example 1, wherein the spacer encapsulates surface mounted components disposed on the substrate.

Example 17. A method for fabricating a chip package including: attaching an integrated circuit (IC) die complex to a substrate; disposing a spacer on a top surface of the substrate, the spacer at least partially surrounding the IC die complex; and attaching a stiffener to the top surface of the substrate and to a top surface of the spacer.

Example 18. The method of Example 17 further including: disposing underfill in contact with one or more of the top surface of the spacer and/or a top surface of the IC die complex, the underfill contacting an inner wall of the stiffener.

Example 19. The method of Example 17, wherein disposing the spacer on the top surface of the substrate further includes: encapsulating surface mounted components disposed on the top surface of the substrate.

Example 20. The method of Example 17, wherein disposing the spacer on the top surface of the substrate further includes: dispensing adhesive on a top surface of the spacer.

Thus, chip packages that mitigate the potential warpage, along with techniques for fabricating the same, have been described above. The chip packages described above leverage a flanged stiffener to mitigate warpage. The stiffener is attached to a periphery of the substrate as well as to the spacer using adhesive materials. The attachment of the stiffener at inner and outer locations advantageously enhances the resistance to warpage, thus making the chip package much more robust and reliable compared to conventional designs. Moreover, surface mounted components, such as capacitors and the like, can be protectively encapsulated by the spacer. In other examples, the ring-shaped stiffener includes a central opening through which the top surface of the chip complex is exposed, thus allowing thermal solutions to be directly interfaced with the chip complex (i.e., without an intervening lid or cover) resulting in enhanced heat transfer and computing performance.

What is claimed is:

1. A chip package comprising:
a substrate;
an integrated circuit (IC) die complex mechanically connected to the substrate;
a spacer formed on a top surface of the substrate outward of the IC die complex; and
a stiffener comprising:
a ring base having a bottom surface attached to the top surface of the substrate; and
a flange extending inward from the ring base, the flange having a bottom surface attached to the top surface of the spacer.

2. The chip package of claim 1, wherein an inner wall of the stiffener defines an opening through which a top surface of the IC die complex is exposed.

3. The chip package of claim 1 further comprising:
a first adhesive attaching the bottom surface of the flange to the top surface of the spacer.

4. The chip package of claim 3 further comprising:
a second adhesive attaching the bottom surface of the ring base to the top surface of the substrate.

5. The chip package of claim 4, wherein at least one of the first and second adhesives have a service temperature of at least 240 degrees Celsius.

6. The chip package of claim 4, wherein at least one of the first and second adhesives is polymer based or silica based.

7. The chip package of claim 1 further comprising:
underfill contacting one or more of an inner wall of the flange of the stiffener, the top surface of the spacer, and a top surface of the IC die complex is exposed.

8. The chip package of claim 1, wherein the spacer is fabricated from a polymeric material.

9. The chip package of claim 1, wherein the spacer encapsulates surface mounted components disposed on the substrate.

10. The chip package of claim 9, wherein the surface mounted components are capacitors.

11. A chip package comprising:
a substrate;
an integrated circuit (IC) die complex mechanically connected to the substrate;
a spacer formed on a top surface of the substrate and surrounds the IC die complex;
a stiffener attached to the top surface of the substrate and to the spacer; and
a thermal regulating device engaged with the IC die through an opening in the stiffener.

12. The chip package of claim 11, wherein the thermal regulating device comprises a pad extending through the opening of the stiffener; and
thermal interface material contacting the pad of the thermal regulating device and the top surface of the IC die complex.

13. The chip package of claim 11, further comprising an adhesive having a service temperature of at least 240 degrees Celsius attaching the stiffener to the top surface of the substrate.

14. The chip package of claim 13, wherein the adhesive is polymer based or silica based.

15. The chip package of claim 11 further comprising:
underfill contacting one or more of an inner wall of the flange of the stiffener, and a top surface of the spacer.

16. The chip package of claim 11, wherein the spacer encapsulates surface mounted components disposed on the substrate.

17. A method for fabricating a chip package comprising:
attaching an integrated circuit (IC) die complex to a substrate;
disposing a spacer on a top surface of the substrate, the spacer at least partially surrounding the IC die complex; and
attaching a stiffener to the top surface of the substrate and to a top surface of the spacer.

18. The method of claim 17 further comprising:
disposing underfill in contact with one or more of the top surface of the spacer and/or a top surface of the IC die complex, the underfill contacting an inner wall of the stiffener.

19. The method of claim 17, wherein disposing the spacer on the top surface of the substrate further comprises:
encapsulating surface mounted components disposed on the top surface of the substrate.

20. The method of claim 17, wherein disposing the spacer on the top surface of the substrate further comprises:
dispensing adhesive on a top surface of the spacer.
